(19) United States
(12) Patent Application Publication
(10) Pub. No.: US 2024/0304757 A1
(43) Pub. Date: Sep. 12, 2024

(54) VERTICAL STRUCTURE DEEP ULTRAVIOLET LIGHT EMITTING DIODE, MANUFACTURING METHOD THEREOF AND EPITAXIAL STRUCTURE

(71) Applicant: XIAMEN SILAN ADVANCED COMPOUND SEMICONDUCTOR CO., LTD., Xiamen (CN)

(72) Inventors: Weihong Fan, Xiamen (CN); Jingfeng Bi, Xiamen (CN); Maofang Guo, Xiamen (CN); Shitao Li, Xiamen (CN); Jinchao Zhao, Xiamen (CN); Shiman Shi, Xiamen (CN); Quanxin Jin, Xiamen (CN)

(21) Appl. No.: 18/575,021

(22) PCT Filed: Mar. 1, 2022
(86) PCT No.: PCT/CN2022/078631

§ 371 Date: Dec. 28, 2023

(30) Foreign Application Priority Data
Jun. 28, 2021 (CN) 202110717833.X

(51) Int. Cl. H01L 33/32; H01L 25/075; H01L 33/00; H01L 33/06; H01L 33/10; H01L 33/14; H01L 33/38; H01L 33/62

(52) U.S. Cl. CPC H01L 33/32; H01L 25/0753; H01L 33/007; H01L 33/0093; H01L 33/06; H01L 33/10; H01L 33/14; H01L 33/38; H01L 33/62; H01L 2933/0016; H01L 2933/0066

(57) ABSTRACT

Disclosed is a vertical structure deep ultraviolet LED, a manufacturing method thereof and an epitaxial structure. The manufacturing method comprises: forming an epitaxial structure on a sapphire substrate, the epitaxial structure having a first surface and a second surface connected with the sapphire substrate; dividing the epitaxial structure into epitaxial units arranged in an array, a portion of the sapphire substrate being exposed between adjacent epitaxial units; forming an adhesive layer on a portion, which is exposed between adjacent epitaxial units, of the sapphire substrate; bonding a second substrate above the first surface of the epitaxial structure; performing laser lift-off on the sapphire substrate; and removing the adhesive layer. By dividing the epitaxial structure into epitaxial units arranged in an array, the manufacturing method alleviates the problem of serious damage to the epitaxial structure caused by strong impact generated at the moment of high energy density laser lift-off.

### CROSS-REFERENCE TO RELATED APPLICATION

The present application claims priority to Chinese patent application No. CN202110717833.X, filed on Jun. 28, 2021, and entitled “VERTICAL STRUCTURE DEEP ULTRAVIOLET LIGHT EMITTING DIODE, MANUFACTURING METHOD THEREOF AND EPITAXIAL STRUCTURE”, the entire contents of which are incorporated herein by reference in their entireties.

### FIELD OF THE DISCLOSURE The present disclosure relates to a technical field of semiconductor manufacturing,

and in particular, to a vertical structure deep ultraviolet light emitting diode, a manufacturing method thereof and an epitaxial structure.

### DESCRIPTION OF THE RELATED ART

In related technologies, a deep ultraviolet LED (Light Emitting Diode) may have low quantum efficiency, and main reasons are as follows: firstly, the epitaxial quality of deep ultraviolet AlGaN is not ideal enough, and high defect density leads to low internal quantum efficiency; secondly, in order to obtain better ohmic contact effect, a p-GaN layer needs to be grown as a contact layer on a P-type semiconductor layer, the p-GaN layer can strongly absorb deep ultraviolet light, while if a p-AlGaN contact layer is used instead of the p-GaN layer, a voltage of the deep ultraviolet LED will increase significantly; thirdly, with an increase of Al composition in a quantum well, light emitted by the deep ultraviolet LED is mainly in TM (transverse magnetic) mode (parallel to a light-emitting surface), it is difficult for TM mode light to enter an escape cone of the light-emitting surface and exit to outside of the deep ultraviolet LED, and light extraction efficiency in TM mode is only one tenth of that in TE (transverse electric) mode (perpendicular to the light-emitting surface), these problems seriously restrict performance improvement of the deep ultraviolet LED.

To achieve acceptable light intensity, a deep ultraviolet AlGaN epitaxial layer can be grown on a sapphire substrate and a flip-chip structure can be used. To increase a proportion of sidewall area, a striped electrode and patterned MESA technology can be used. And to obtain more rough light-emitting surfaces, the sapphire substrate can be retained with a large thickness and a roughening process can be performed on the sidewall of the sapphire substrate. Sapphire can be chosen as a heterogeneous substrate for deep ultraviolet epitaxial growth, mainly because other materials (such as AlN, GaN, SiC), which may match crystal lattice of a deep ultraviolet AlGaN epitaxial layer, are expensive and have greater absorption of deep ultraviolet light than sapphire, thus, generally, those materials (such as AlN, GaN, SiC) are seldomly used. However, a deep ultraviolet LED with flip-chip structure prepared by epitaxial growth technology based on sapphire substrate still has several disadvantages: on the one hand, there is a refractive index difference between the sapphire substrate and the air, so that the light extraction efficiency still does not reach a relatively ideal level, and it is necessary to design a reflector with complex structure to improve light extraction performance; on the other hand, the sapphire substrate with a relatively large thickness will bring adverse effects on chip dicing process, resulting in great reduction in stealth laser dicing productivity and chip yield; more importantly, the thermal conductivity of flip-chip structure still does not reach an good level, which will adversely affect the reliability of the deep ultraviolet LED.

A technical scheme using vertical structure deep ultraviolet LED is a better choice. A substrate of vertical structure LED is designed to be electricity conductive and thermal conductive, therefore, on the one hand, operating current density of the deep ultraviolet LED can be significantly increased, so that a single deep ultraviolet LED can provide more luminescence, and a purpose of increasing external quantum efficiency of the deep ultraviolet LED can be realized by processing various patterned light extraction structures on a light-emitting surface of the deep ultraviolet LED and a sidewall of the deep ultraviolet LED, thereby greatly improving electro-optical conversion efficiency of the deep ultraviolet LED; on the other hand, because of its remarkable improvement in thermal conductivity, it can also greatly improve the reliability of the deep ultraviolet LED.

For vertical structure blue-green and near-ultraviolet LEDs, an epitaxial layer or a bottom buffer layer grown on the sapphire substrate is mainly made of GaN (corresponding to a light-emitting wavelength of about 360 nm), therefore, using deep ultraviolet laser with a wavelength lower than 360 nm, such as 266 nm, 248 nm, 193 nm or other wavelength within that range, laser lift-off can be realized based on the principle that GaN absorbs laser energy and performs decomposition; a melting point of Ga obtained by the decomposition of GaN is very low, so it is easy to separate the epitaxial layer from the sapphire substrate after laser lift-off.

For the vertical structure deep ultraviolet LED, the epitaxial layer is mainly composed of AlN or AlGaN with high Al composition, and a corresponding light-emitting wavelength of AlN is about 200 nm, so only laser of lower wavelength, such as 193 nm ArF excimer laser, can realize the separation of AlN and sapphire substrate; at the same time, in the process of laser lift-off, due to a high melting point and strong adhesion of Al, which is obtained by the decomposition of AlN, it is easy to break the epitaxial layer when separating the epitaxial layer from the sapphire substrate. In some other solutions, AlₓGa₁₋ₓN/Al_{y}Ga_{1-y}N superlattice structure may be used as a sacrificial layer, and the lift-off of the sapphire substrate may be achieved by using laser with a wavelength of 248 nm or 266 nm. However, because the superlattice structure is too close to the multi-quantum well layer in the epitaxial layer, and laser threshold energy for lifting off AlN is about 1.0 J/mm² (while laser threshold energy for lifting off GaN is about 0.4-0.6 J/mm², which is only half of that for lifting off AlN), a strong impact produced at the moment of high energy density laser lift-off will cause serious damage to the epitaxial layer of the deep ultraviolet LED, in addition, the AlN layer with a large thickness in the epitaxial layer of the deep ultraviolet LED has serious stress effect, and superlattice lift-off will lead to serious LED failure. If small laser light spot is used for continuous lift-off process, lattice and thermal mismatch of sapphire-AlN—GaN will be more obvious, and stress phenomenon in this material system will be more serious. In a laser lift-off process using small light spot with high energy density, the epitaxial layer of deep ultraviolet LED will be inevitably cracked in overlap area of each small light spot unit, which will lead to a failure of the entire device, and it is impossible to obtain a die with larger size.

In addition, for a deep ultraviolet LED with N-up vertical structure, after lifting off the sapphire substrate from the epitaxial structure, it is necessary to form an N-electrode electrically connected with the n-AlGaN layer (N-type semiconductor layer) of the light-emitting surface. However, after the lift-off process, the n-AlGaN layer with N polarity on a side corresponding to the light-emitting surface may have an ohmic contact effect worse than that of an n-AlGaN layer with Ga/Al polarity. Moreover, because the N-electrode is located above the light-emitting surface, the material of the N-electrode is limited to be a transparent conductive material for ensuring the light output of the deep ultraviolet LED, which is more difficult to prepare.

Therefore, it is necessary to provide an improved deep ultraviolet LED and a manufacturing method thereof in order to overcome problems as described above.

### SUMMARY OF THE DISCLOSURE

In view of the above problems, an objective of the present disclosure is to provide a vertical structure deep ultraviolet light emitting diode (LED), a manufacturing method thereof and an epitaxial structure, wherein by dividing the epitaxial structure into a plurality of epitaxial units arranged in an array, it is unnecessary to use a large-size laser light spot to irradiate an AlN layer of the whole die area during a lift-off process performed to AlN, and an area of the light spot can be set more flexibly according to a size corresponding to the epitaxial units; at the same time, an adhesive layer is formed on a portion, which is exposed between adjacent epitaxial units, of a sapphire substrate, and can be used as a stress release structure to reduce a probability of the epitaxial structure cracking of AlN during the lift-off process: in addition, because the epitaxial structure is divided into the plurality of epitaxial units arranged in the array, it is beneficial to extract more deep ultraviolet light in horizontal direction, thus improving the light-emitting efficiency of the deep ultraviolet LED.

According to a first aspect of embodiments of the present disclosure, a manufacturing method of a vertical structure deep ultraviolet LED is provided, and comprises: forming an epitaxial structure on a sapphire substrate, the epitaxial structure having a first surface and a second surface, the second surface being connected to the sapphire substrate: dividing the epitaxial structure into a plurality of epitaxial units arranged in an array, a portion of the sapphire substrate being exposed between adjacent ones of the plurality of epitaxial units: forming an adhesive layer on a portion, which is exposed between adjacent ones of the plurality of epitaxial units, of the sapphire substrate: bonding a second substrate above the first surface of the epitaxial structure: performing laser lift-off to the sapphire substrate: and removing the adhesive layer.

Optionally, the epitaxial structure includes an AlN layer exposed to the second surface, and the step of performing laser lift-off to the sapphire substrate includes: irradiating the AlN layer in each of the plurality of epitaxial units with laser through the sapphire substrate to decompose an irradiated portion of the AlN layer into Al metal and nitrogen gas: and removing the Al metal by chemical wet etching process to separate the sapphire substrate from the epitaxial structure.

Optionally, the step of irradiating the AlN layer in each of the plurality of epitaxial units with laser through the sapphire substrate to decompose the irradiated portion of the AlN layer into Al metal and nitrogen gas comprises: decomposing the irradiated portions of the AlN layer in the plurality of epitaxial units into Al metal and nitrogen gas one by one using an ArF excimer laser lift-off process.

Optionally, a solution for removing Al metal by chemical wet etching process is one of weak acidic dilute hydrochloric acid, oxalic acid, hydrofluoric acid and BOE (Buffered Oxide Etchant) solutions, or one of weak alkaline KOH, NaOH and TMAH (Tetramethylammonium Hydroxide) solutions.

Optionally, the adhesive layer is made of cured UV (ultraviolet) adhesive or polydimethylsiloxane.

Optionally, the array is a rectangular array or a hexagonal array, and a spacing between adjacent ones of the plurality of epitaxial units is greater than 50 μm.

Optionally, the epitaxial structure further comprises: a P-type semiconductor layer, an N-type semiconductor layer, a multi-quantum well layer sandwiched between the P-type semiconductor layer and the N-type semiconductor layer, and a superlattice layer between the N-type semiconductor layer and the AlN layer, wherein the P-type semiconductor layer is exposed to the first surface of the epitaxial structure, and the step of dividing the epitaxial structure into the plurality of epitaxial units arranged in the array comprises: forming a first trench penetrating the P-type semiconductor layer and the multi-quantum well layer, wherein a portion of a surface of the N-type semiconductor layer is exposed to the first trench: forming a second trench penetrating the N-type semiconductor layer, the superlattice layer and the AlN layer through the first trench, wherein a portion of the sapphire substrate is exposed to the second trench, the first trench is connected with the second trench to divide the epitaxial structure into the plurality of epitaxial units arranged in the array, wherein the adhesive layer is filled in the second trench.

Optionally, a width of the second trench is less than a width of the first trench, each of the epitaxial units includes a first mesa unit and a second mesa unit, adjacent first mesa units are separated by the first trench, adjacent second mesa units are separated by the second trench, in each of the plurality of epitaxial units, the second mesa unit has a mesa surface protruding from the first mesa unit, a portion of the N-type semiconductor layer is exposed to the mesa surface, and the manufacturing method further includes: forming an N-type ohmic contact on each of the mesa surfaces, the N-type ohmic contact is connected with the N-type semiconductor layer.

Optionally, along a direction from the first surface to the second surface of the epitaxial structure, a cross-sectional shape of the first mesa unit is a trapezoid or an inverted trapezoid, and a cross-sectional shape of the second mesa unit is a trapezoid or an inverted trapezoid.

Optionally, the manufacturing method further comprises: forming a P-type ohmic contact layer on the P-type semiconductor layer of each of the plurality of epitaxial units: forming a reflector layer on the P-type ohmic contact layer of each of the plurality of epitaxial units: forming a P-type current spreading layer on the reflector layer of each of the plurality of epitaxial units.

Optionally, an opening of the first trench extends to the P-type current spreading layer, and the manufacturing method further includes: forming a first thermal conductive dielectric layer covering the P-type current spreading layer, a sidewall of the first trench, a portion, which is exposed to the mesa surface, of the N-type semiconductor layer, and the adhesive layer, wherein the first thermal conductive dielectric layer has a contact hole exposing the N-type ohmic contact.

Optionally, the manufacturing method further includes: forming an N-type current spreading layer covering the first thermal conductive dielectric layer, wherein the N-type current spreading layer is connected to each of the N-type ohmic contacts via the contact hole, and the N-type current spreading layer has an opening which corresponds to each of the plurality of epitaxial units and exposes the first thermal conductive dielectric layer.

Optionally, the manufacturing method further includes: forming a second thermal conductive dielectric layer covering the N-type current spreading layer, wherein a portion of the second thermal conductive dielectric layer is filled in the opening of the N-type current spreading layer and is connected with the first thermal conductive dielectric layer: and forming a P-type conductive via which passes through the second thermal conductive dielectric layer and the first thermal conductive dielectric layer in sequence at each opening of the N-type current spreading layer to expose a portion of the P-type current spreading layer.

Optionally, the step of bonding the second substrate above the first surface of the epitaxial structure includes: forming a first bonding layer covering the second thermal conductive dielectric layer, the first bonding layer being connected to the P-type current spreading layer through the P-type conductive via: forming a second bonding layer on the second substrate: bonding the first bonding layer with the second bonding layer.

Optionally, the step of removing the adhesive layer includes: removing the adhesive layer using plasma etching process.

Optionally, the manufacturing method further includes: forming a passivation layer covering the second surface of the epitaxial structure and sidewalls of each of the second mesa units, wherein the passivation layer is connected with the first thermal conductive dielectric layer.

Optionally, the manufacturing method further includes: forming a P-electrode, wherein the P-electrode and the second bonding layer are respectively located on opposite sides of the second substrate; and forming an N-electrode at an edge of the epitaxial structure, the N-electrode being connected to the N-type current spreading layer through the first thermal conductive dielectric layer along a direction from the second surface to the first surface.

Optionally, the second substrate is a metal substrate, and the manufacturing method further includes: dicing the metal substrate to separate adjacent deep ultraviolet LEDs, by using one of dicing processes including water-jet guided laser dicing process and laser dicing process, and one of dicing schemes including single-sided dicing scheme and double-sided dicing scheme.

According to a second aspect of embodiments of the present disclosure, an epitaxial structure of a vertical structure deep ultraviolet LED is provided, the epitaxial structure has a first surface and a second surface opposite to the first surface, and is divided into a plurality of epitaxial units arranged in an array, each of the plurality of epitaxial units includes an AlN layer, a P-type semiconductor layer, an N-type semiconductor layer, and a multi-quantum well layer sandwiched between the P-type semiconductor layer and the N- type semiconductor layer, the P-type semiconductor layer is exposed to the first surface of the epitaxial structure, and the AlN layer is exposed to the second surface of the epitaxial structure.

Optionally, each of the plurality epitaxial units comprises a first mesa unit and a second mesa unit, wherein the first mesa unit comprises the P-type semiconductor layer and the multi-quantum well layer, the second mesa unit comprises the AlN layer and the N-type semiconductor layer, and the second mesa unit has a mesa surface protruding from the first mesa unit.

Optionally, the array is a rectangular array or a hexagonal array, and a spacing between adjacent ones of the plurality of epitaxial units is greater than 50 μm.

Optionally, along a direction from the first surface to the second surface of the epitaxial structure, a cross-sectional shape of the first mesa unit is a trapezoid or an inverted trapezoid, and a cross-sectional shape of the second mesa unit is a trapezoid or an inverted trapezoid.

According to a third aspect of embodiments of the present disclosure, a vertical structure deep ultraviolet LED is provided, and comprises: an N-type ohmic contact, an N-type current spreading layer, an N-electrode, a P-type ohmic contact layer, a reflector layer, a bonding layer, a substrate, a P-electrode and a thermal conductive dielectric layer; and an epitaxial structure, which has a first surface and a second surface opposite to the first surface, and is divided into a plurality of epitaxial units arranged in an array, wherein each of the plurality of epitaxial units includes a P-type semiconductor layer, an N-type semiconductor layer and a multi-quantum well layer sandwiched between the P-type semiconductor layer and the N-type semiconductor layer, and the P-type semiconductor layer is exposed to the first surface of the epitaxial structure.

Optionally, each of the plurality of epitaxial units has a first mesa unit and a second mesa unit, wherein the first mesa unit comprises the P-type semiconductor layer and the multi-quantum well layer, the second mesa unit comprises the AlN layer and the N-type semiconductor layer, and the second mesa unit has a mesa surface protruding from the first mesa unit.

Optionally, the epitaxial structure further includes an AlN layer exposed to the second surface of the epitaxial structure, and the second mesa unit further includes the AlN layer.

Optionally, the array is a rectangular array or a hexagonal array, and a spacing between adjacent ones of the plurality of epitaxial units is greater than 50 μm.

Optionally, along a direction from the first surface to the second surface of the epitaxial structure, a cross-sectional shape of the first mesa unit is a trapezoid or an inverted trapezoid, and a cross-sectional shape of the second mesa unit is a trapezoid or an inverted trapezoid.

Optionally, a portion of the N-type semiconductor layer is exposed to the mesa surface, and the N-type ohmic contacts are located on each of the mesa surfaces, respectively, and are connected to the N-type semiconductor layer.

Optionally, the N-type current spreading layer is respectively connected with each of the N-type ohmic contacts, wherein, the N-type current spreading layer and each of the N-type ohmic contacts are located on a same side of the N-type semiconductor layer, and deep ultraviolet light is emitted from the second surface of the epitaxial structure.

Optionally, the vertical structure deep ultraviolet LED further comprises: an array of reflector layers and an array of P-type current spreading layers, wherein an array of the P-type ohmic contact layers are located on the first surface of the epitaxial structure and each of the P-type ohmic contact layers is connected with the P-type semiconductor layer in a corresponding one of the plurality of epitaxial units, and each of the reflector layers is located between a corresponding one of the P-type current spreading layers and a corresponding one of the P-type ohmic contact layers.

Optionally, the thermal conductive dielectric layer and each of the N-type ohmic contacts are located on a same side of the N-type semiconductor layer, the thermal conductive dielectric layer wraps the first mesa units and the array of the P-type ohmic contact layers, the array of the P-type current spreading layers and the array of the reflector layers, and extends to the mesa surface, adjacent ones of the mesa surfaces are connected by the thermal conductive dielectric layer, and the thermal conductive dielectric layer is exposed between the adjacent second mesa units along a direction from the second surface to the first surface, wherein, each of the N-type ohmic contacts and the N-type current spreading layer are located in the thermal conductive dielectric layer.

Optionally, along a direction from the second surface to the first surface, the thermal conductive dielectric layer is also exposed at an edge of the epitaxial structure, the N-electrode is located at the edge of the epitaxial structure, and is connected to the N-type current spreading layer through a portion of the thermal conductive dielectric layer along a direction from the second surface to the first surface.

Optionally, the bonding layer includes a first bonding layer and a second bonding layer, along a direction from the second surface to the first surface, the first bonding layer, the second bonding layer, the substrate and the P-electrode are connected in sequence, wherein the first bonding layer and the thermal conductive dielectric layer are located on a same side of the N-type semiconductor layer and the first bonding layer is connected with a surface of the thermal conductive dielectric layer, and along a direction from the first surface to the second surface, the first bonding layer is connected with each of the P-type current spreading layers through the thermal conductive dielectric layer, and the first bonding layer and the N-type current spreading layer are separated by the thermal conductive dielectric layer.

Optionally, the substrate is a metal substrate.

Optionally, the vertical structure deep ultraviolet LED further comprises: a passivation layer covering the second surface of the epitaxial structure and sidewalls of each of the second mesa units, and connected with the thermal conductive dielectric layer.

Optionally, each of the plurality of epitaxial units further includes a superlattice structure layer, and in each of the second mesa units, the superlattice structure layer is located between the AlN layer and the N-type semiconductor layer.

According to vertical structure deep ultraviolet LEDs and manufacturing methods thereof provided by embodiments of the present disclosure, by dividing an epitaxial structure into a plurality of epitaxial units arranged in an array, when an AlN layer in each epitaxial unit is irradiated by laser through a sapphire substrate, an area of laser light spot can be set more flexibly according to a size corresponding to the epitaxial units (for example, the area of the laser light spot is set to be slightly larger than a size of a single epitaxial unit or an overall size of two or more of the plurality of epitaxial units), instead of setting the light spot to have a large area matched with an overall size of the vertical structure deep ultraviolet LED, thus mitigating a problem of serious damage to the epitaxial structure caused by strong impact generated at a moment of high energy density laser lift-off.

An adhesive layer is formed on a portion, which is exposed between adjacent epitaxial units, of the sapphire substrate. When the irradiated AlN layers in the epitaxial units are decomposed into Al metal and nitrogen gas one by one by laser lift-off process, high pressure nitrogen gas release and plasma impact on adjacent epitaxial units produced at a moment of laser lift-off can be reduced, that is, a probability of the epitaxial structure cracking in the lift-off process of AlN material can be reduced by using this adhesive layer as a stress release structure.

Furthermore, the adhesive layer can be made of cured UV adhesive or polydimethylsiloxane, which has stronger support strength compared with resin material, and can solve a problem of serious failure caused by aging of resin material under deep ultraviolet irradiation, thereby improving lift-off yield and reliability of the deep ultraviolet LED.

The sapphire substrate is separated from the epitaxial structure by dissolving the Al metal produced by decomposing the AlN layer by chemical wet etching process, and then the sapphire substrate is lifted off from the epitaxial structure. The chemical wet etching process adopts weak acidic or weak alkaline solution, which can reduce the probability of damage caused by etching solution to materials other than Al metal.

In the deep ultraviolet LED, each epitaxial unit is divided into two parts: a first mesa unit and a second mesa unit, the second mesa unit has a mesa surface protruding from the first mesa unit, and the N-type semiconductor layer is exposed to the mesa surface, so that the N-type ohmic contact can be directly deposited on the mesa surface (on a surface of Ga/Al polarity N-AlGaN). Compared with the surface contact of metal and N polarity N-AlGaN in the prior art, the ohmic contact performance and stability of the metal-N-type semiconductor are improved, thereby alleviating the voltage problem of the deep ultraviolet LED and realizing a more reasonable voltage level of the deep ultraviolet LED.

Because the N-type ohmic contact and the N-type current spreading layer are located on a same side of the N-type semiconductor layer and opposite to the light-emitting surface, the N-electrode located at the edge of the epitaxial structure is connected with each N-type ohmic contact through the N-type current spreading layer, which replaces the scheme of forming the N-electrode on the light-emitting surface of the N-type semiconductor layer and reduces shielding effect on the light-emitting surface caused by the N-electrode. By arranging a plurality of N-type ohmic contacts on the N-type semiconductor layer and increasing the number of the plurality of N-type ohmic contacts or a contact area of the N-type ohmic contacts with the N-type semiconductor layer, a problem of poor current spreading performance due to the natural characteristics of the n-AlGaN layer can be alleviated. Further, combined with a layout distribution of the N-type current spreading layer, point-shaped N-electrode (or small-size N-electrode) can provide power supply to the N-type semiconductor layer in each epitaxial unit.

In addition, by controlling the morphology of the first trench and the second trench, making the cross sections of the first mesa unit and the second mesa unit each be a trapezoid or an inverted trapezoid in shape, area of a sidewall of each epitaxial unit is increased, thus facilitating the extraction of more horizontal deep ultraviolet light, and further improving the light-emitting effect of the deep ultraviolet LED.

Therefore, the vertical structure deep ultraviolet LED provided by embodiments of the present disclosure can operate under large current and high thermal conduction conditions, and has great significance for realizing industrialization of high-standard deep ultraviolet LED.

### BRIEF DESCRIPTION OF THE DRAWINGS

In order to more clearly explain the technical aspects of the embodiments of the present application, the drawings of the embodiments will be briefly introduced below, and it will be obvious that the drawings in the following description refer to only some embodiments of the present application, and are not limitations of the present application.

FIGS. 1 to 18 show structural diagrams corresponding to some stages of a manufacturing method of a deep ultraviolet LED according to a first embodiment of the present disclosure;

FIGS. 19 to 25 show structural diagrams corresponding to some stages of a manufacturing method of a deep ultraviolet LED according to a second embodiment of the present disclosure.

### DETAILED DESCRIPTION OF EMBODIMENTS OF THE DISCLOSURE

The present disclosure will be described in more details below with reference to the accompanying drawings. Throughout the various figures, like elements are denoted by like reference numerals. For the sake of clarity, various parts in the drawings are not drawn to scale. In addition, some well-known parts may not be shown. For the sake of simplicity, the semiconductor structure obtained after several steps can be described in one diagram.

It should be understood that, when describing a structure of a device, when referring to one layer/region as “above” or “on” another layer/region, it may mean that it is directly above another layer/area, or that there is other layer/region located between the one layer/region and the another layer/region. And, if the device is flipped, the one layer/region will be located “below” or “under” the another layer/region.

In order to describe the situation of being directly located on another layer/region, the present disclosure will use “directly on . . . ” or “on and adjacent to . . . ” or other expressions.

Hereinafter, many specific details of the present disclosure, such as structure, material, dimension, processing process and technique of a device, are described in order to make the present disclosure more clearly understood. However, as will be understood by those skilled in the art, the present disclosure may be practiced without these specific details.

In order to solve the above problems, the present disclosure provides an improved deep ultraviolet LED and a manufacturing method thereof. By dividing an epitaxial structure into a plurality of epitaxial units arranged in an array, it is unnecessary to use a large-size laser light spot to irradiate an AlN layer of the whole die area during lift-off process of AlN material, and an area of the light spot can be set more flexibly according to a size corresponding to the epitaxial units; at the same time, an adhesive layer is formed on a portion, which is exposed between adjacent epitaxial units, of the sapphire substrate, and can be used as a stress release structure to reduce a probability of the epitaxial structure cracking of AlN material during lift-off process: in addition, because the epitaxial structure is divided into the plurality of epitaxial units arranged in the array, it is beneficial to extract more horizontal deep ultraviolet light, thus improving light-emitting efficiency of the deep ultraviolet LED. The present invention may be presented in various forms, some examples of which will be described below.

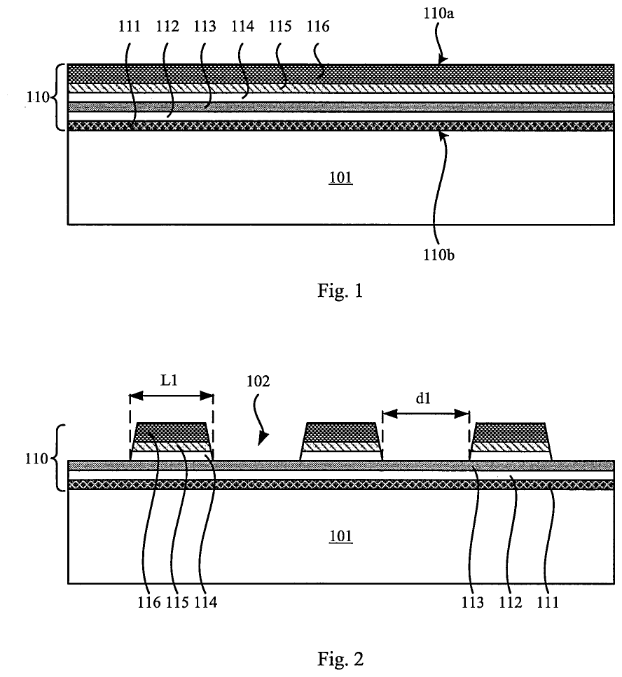

FIGS. 1 to 18 show structural diagrams of some stages of a manufacturing method of a deep ultraviolet LED according to a first embodiment of the present disclosure.

As shown in FIG. 1, an epitaxial structure 110 is formed on a sapphire substrate 101. The epitaxial structure 110 has a first surface 110a and a second surface 110b which is opposite to the first surface 110a and is connected to the sapphire substrate 101. Along a direction from the second surface 110b to the first surface 110a of the epitaxial structure 110, the epitaxial structure 110 includes an AlN layer 111, a superlattice structure layer 112, an N-type semiconductor layer 113, a multi-quantum well layer 114, a P-type AlGaN layer 115, and a P-type GaN layer 116 stacked on the sapphire substrate 101 in sequence, wherein the AlN layer 111 includes an AlN buffer layer on the sapphire substrate 101 and a thick AlN layer on the AlN buffer layer, and the superlattice structure layer 112 is located on the thick AlN layer.

A thickness of the epitaxial structure 110 ranges from 5 μm to 10 μm, and a growth method for each layer in the epitaxial structure 110 may be metal-organic chemical vapor deposition, laser assisted molecular beam epitaxy, laser sputtering, hydride vapor phase epitaxy, etc. Each layer of the epitaxial structure 110 may be a polycrystalline or single-crystal structure. The P-type AlGaN layer 115 and the P-type GaN layer 116 in the epitaxial structure 110 constitute a P-type semiconductor layer. Material of the N-type semiconductor layer 114 is AlGaN with N-type dopant. The multi-quantum well layer 114 in the epitaxial structure 110 includes one or several of reciprocating continuous progressive LED epitaxial structures (e.g., periodically repeating structure) formed by AlGaN/AlInGaN and other material systems, and optionally, the multi-quantum well layer 114 includes AlGaN structures of different Al compositions, corresponding to wavelengths ranging from 360 nm to 200 nm.

The AlN layer 111 and the superlattice structure layer 112 are used to achieve better lattice match between the N-type semiconductor layer 113 and the sapphire substrate 101. The sapphire substrate 101 comprises but is not limited to one of a specular or micron/nano-sized convex/concave patterned sapphire substrate, and optionally, the sapphire substrate 101 comprises specular sapphire. The sapphire substrate 101 may also be provided with one of a pre-deposited AlN film, BAlN film, BN film and graphene film.

The superlattice structure layer 112 is used to coordinate lattice mismatch between AlGaN material and the AlN layer 111. Specifically, for example, 20 pairs of AlₓGa₁₋ₓN/Al_{y}Ga_{1-y}N superlattice structures with graded (gradually reduced) Al composition are prepared along a direction from the AlN layer 111 to the N-type semiconductor layer 113, wherein 0<y<x<1.

Further, a portion of the epitaxial structure 110 is removed to form a first trench 102, as shown in FIG. 2.

In this step, the first trench 102 is formed, for example, by performing photolithography and dry etching process, wherein the dry etching is controlled to stop when reaching the vicinity of the surface of the N-type semiconductor layer 113. A stacked structure composed of the multi-quantum well layer 114, the P-type AlGaN layer 115, and the P-type GaN layer 116 is divided into a plurality of first mesa units by one or more first trenches 102.

The plurality of first mesa units are arranged in an array, which is, for example, a rectangular or hexagonal array. Wherein, a planar shape (top-view shape) of each first mesa unit is one or a combination of some of a circle, a regular polygon, a rectangle and a diamond. A critical dimension of the shape of each first mesa unit ranges from 50 μm to 500 μm. A cross-sectional shape, which is obtained along a thickness direction of the epitaxial layer structure 110, of each of the first mesa units is one of a trapezoid or an inverted trapezoid, thereby increasing the sidewall area of each of the first mesa units.

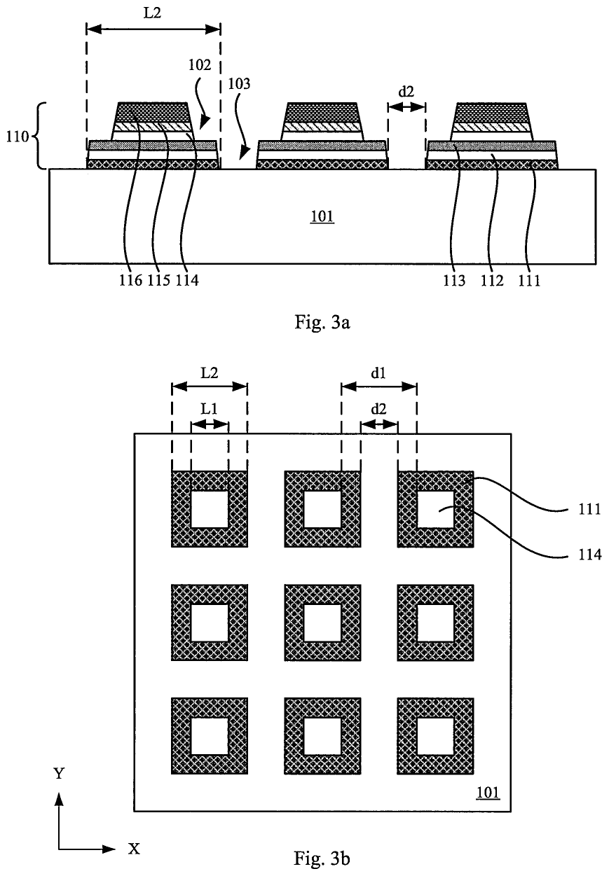

Further, a portion of the epitaxial structure 110 is removed, thus a second trench 103 is formed, as shown in FIGS. 3a and 3b, wherein, FIG. 3b shows a schematic diagram, which is obtained at a plane perpendicular to the thickness direction of the epitaxial structure 110, of an array of the epitaxial units, and for clarity of expression, only the sapphire substrate 101, the AlN layer 111, and the multi-quantum well layer 114 are shown.

In this step, the second trench 103 is formed, for example, by performing photolithography and dry etching process, wherein the dry etching is controlled to stop when reaching the vicinity of the surface of the sapphire substrate 101. A stacked structure composed of the N-type semiconductor layer 113, the superlattice structure layer 112, and the AlN layer 111 is divided into a plurality of second mesa units by one or more second trenches 103, the plurality of second mesa units have one-to-one correspondence to the plurality of first mesa units, respectively, in position and shape, and a critical dimension of a planar shape of each second mesa unit is 50 μm to 500 μm larger than a critical dimension of a planar shape of each first step unit. A cross-sectional shape, which is obtained along the thickness direction of the epitaxial layer structure 110, of each of the second mesa units, is one of a trapezoid or an inverted trapezoid, thereby increasing the sidewall area of each of the second mesa units. The first trench 102 is connected with the second trench 103 to form a complete isolation trench. By setting the isolation trench, the sidewall area of the epitaxial structure 110 is increased, which is beneficial to extract more deep ultraviolet light in the horizontal direction.

In this embodiment, a mesa-unit group composed of a first mesa unit and a second mesa unit corresponding to that first mesa unit constitutes one of the epitaxial units. It should be noted that the number of epitaxial units in a die is not limited to the number of epitaxial units as shown in the figures. The sapphire substrate 101 and each mesa-unit group of the first mesa units and the second mesa units constitutes a mesa structure, each mesa structure has an upper mesa surface, an intermediate mesa surface and a lower mesa surface. A portion of the sapphire substrate 101 is exposed to the lower mesa surface, a portion of the N-type semiconductor layer 113 is exposed to the intermediate mesa surface, and the P-type GaN layer 116 is exposed to the upper mesa surface. That is, the second mesa unit has a mesa surface protruding from the first mesa unit, and a portion of the N-type semiconductor layer 113 is exposed to that mesa surface.

In some specific embodiments, each of the first mesa units is a frustum of a rectangular pyramid, whose planar shape is a square, and a side length L1 (critical dimension) of a bottom square surface (i.e., the surface, which is adjacent to the N-type semiconductor layer 113, of the multi-quantum well layer 114) of each of the first mesa units is 250 μm. A cross-sectional shape, which is obtained along the thickness direction of the epitaxial layer structure 110, of each of the first mesa units is a trapezoid, that is, each of the first mesa units has a bottom surface area larger than its top surface area. A minimum spacing d1 between adjacent first mesa units is greater than 50 μm, for example, 100 μm. Each of the second mesa units may be a frustum of a rectangular pyramid, whose planar shape is a square, and a side length L2 (critical dimension) of a bottom square surface (i.e., a surface, which is adjacent to the sapphire substrate 101, of the AlN layer 111) of each of the second mesa units is 310 μm. A cross-sectional shape, which is obtained along the thickness direction of the epitaxial layer structure 110, of each of the second mesa units is a trapezoid, that is, each of the second mesa units has a bottom surface area larger than its top surface area. A minimum spacing d2 between adjacent second mesa units is 40 μm to 100 μm, for example, 40 μm. In each mesa-unit group, a center of the first mesa unit coincides with a center of the second mesa unit.

In other specific embodiments, at least one of the sidewall of the first mesa unit and the sidewall of the second mesa unit is parallel to m plane (1010) crystal plane, except for the sidewall(s) parallel to the m plane (1010) crystal plane, other sidewall(s) is designed at an angle of 120 degrees to the sidewall(s) parallel to the m plane (1010) crystal plane, thereby obtaining a { 1010} crystal plane group. Each of the first mesa units is a frustum of a hexagonal pyramid, whose planar shape is a regular hexagon, and each second mesa unit is a frustum of a hexagonal pyramid, whose planar shape is a regular hexagon.

In some other embodiments, the sidewalls of the first mesa units and the second mesa units are, for example, roughened by using one of low concentration alkaline solutions KOH, NaOH, TMAH, wherein concentration of the alkaline solution does not exceed 20%, temperature of the alkaline solution is room temperature or 40° C.˜150° C., and roughening time ranges from 5 min to 60 min.

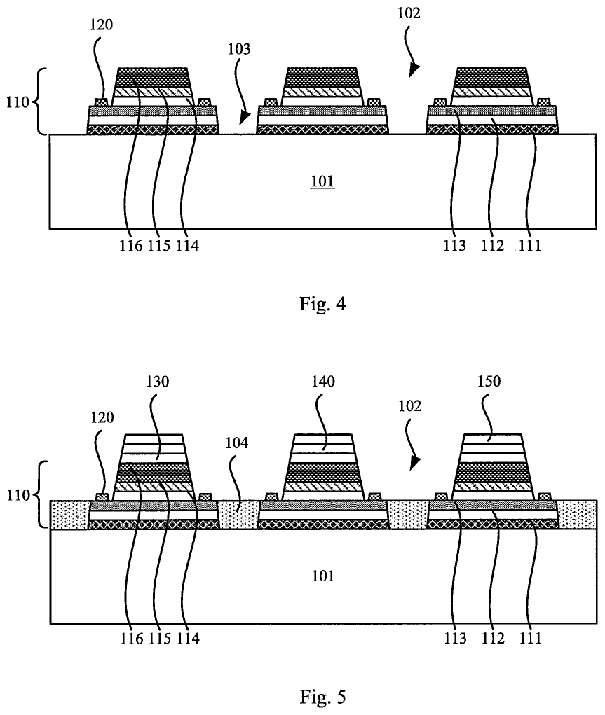

Further, an N-type ohmic contact 120 is formed on the N-type semiconductor layer 113 of each epitaxial unit, as shown in FIG. 4.

In this step, the N-type ohmic contact 120 is formed, for example, by performing photolithography and physical vapor deposition first, and is positioned around the first mesa unit and separated from the multi-quantum well layer 114, the P-type AlGaN layer 115, and the P-type GaN layer 116, respectively. Then, the N-type ohmic contact 120 is subjected to laser or high-temperature rapid thermal annealing (RTA), so that a good ohmic contact can be formed between the N-type ohmic contact 120 and the N-type semiconductor layer 113.

Material of the N-type ohmic contact 120 may include one or a combination of some of V, Hf, Ti, Cr, Al, Ni, Au, and Pt, with a total thickness ranging from 100 nm to 2 μm. The annealing may be performed in N₂ atmosphere, with annealing temperature ranging from 700° C. to 1100° C., and annealing time ranging from 30 sec to 2 min.

In the present embodiment, the N-type ohmic contact 120 may include V, Al, Ti, Pt, and Au metal layers stacked in sequence along a direction from the second surface 110b to the first surface 110a of the epitaxial structure 110, and process temperature for the annealing may be 900° C.

Further, a P-type ohmic contact layer 130 is formed on the P-type GaN layer 116 of each epitaxial unit, as shown in FIG. 5.

In this step, the P-type ohmic contact 130 is formed, for example, by performing photolithography and physical vapor deposition first, and then the P-type ohmic contact layer 130 is subjected to laser or high-temperature rapid thermal annealing, so that a good ohmic contact can be formed between the P-type ohmic contact layer 130 and the P-type GaN layer 116.

Material of the P-type ohmic contact layer 130 may include one or a combination of some of ITO, Ni, NiAu, Pd, and Rh, with a total thickness ranging from 0.1 nm to 100 nm. The annealing may be performed in one of air atmosphere and N₂ atmosphere, with annealing temperature ranging from 350° C. to 700° C., and annealing time ranging from 3 min to 10 min.

In this embodiment, a thickness of the P-type ohmic contact layer 130 may be 20 nm and the P-type ohmic contact layer 130 may be made of ITO.

Further, a reflector layer 140 is formed on the P-type ohmic contact layer 130 of each epitaxial unit, as shown in FIG. 5.

In this step, the reflector layer 140 is formed, for example, by performing photolithography and physical vapor deposition process, in which a region corresponding to the isolation trench is protected and is not covered by the reflector layer 140, or it can be said that, in this step, the opening of the isolation trench extends to the reflector layer 140. The reflector layer 140 has high reflectivity in deep ultraviolet light wavelength.

The reflector layer 140 includes one of an Al reflector, a Rh reflector, and a Mg reflector, or the reflector layer 140 is an omni-directional reflector (ODR) composed of a high thermal conductive dielectric layer and one of an Al reflector, a Rh reflector, and a Mg reflector.

In this embodiment, the reflector layer 140 may be made of Al, Pt, Ti.

Further, a P-type current spreading layer 150 is formed on the reflector layer 140 of each epitaxial unit, as shown in FIG. 5.

In this step, the P-type current spreading layer 150 is formed, for example, by performing photolithography and physical vapor deposition process, in which a region corresponding to the isolation trench is protected, and is not covered by the P-type current spreading layer 150, or it can be said that, in this step, the opening of the isolation trench extends to the P-type current spreading layer 150. The P-type current spreading layer 150 may be made of Cr, Pt, Au.

Further, an adhesive layer 104 is filled in the second trench 103, as shown in FIG. 5.

In this step, the adhesive layer 104 needs to be cured after the adhesive layer 104 is filled into the second trench 103. The adhesive layer 104 is one of heat-resistant UV curing adhesive and PDMS (polydimethylsiloxane), and is cured by ultraviolet or heat so as to obtain better mechanical strength.

In this embodiment, the adhesive layer 104 fills the second trench 103, so that a surface of the adhesive layer 104 is substantially flush with the mesa surface which exposes the N-type semiconductor layer 113, and the adhesive layer 104 is cured by heating and baking.

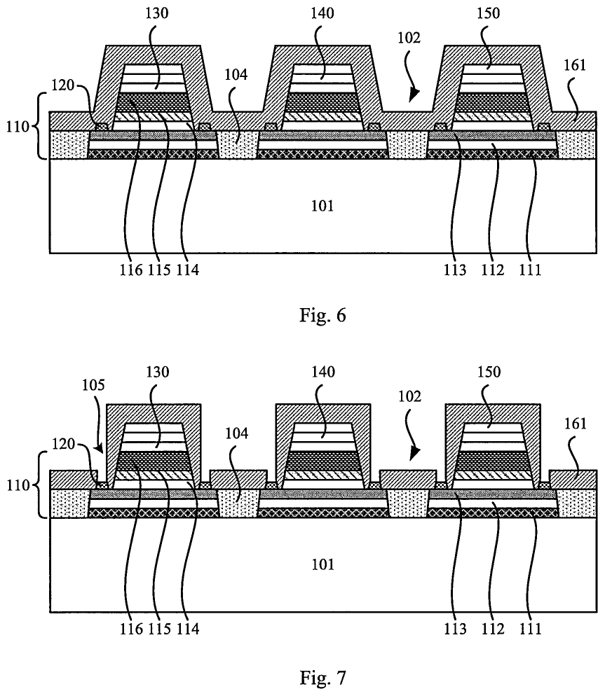

Further, a first thermal conductive dielectric layer 161 is formed, as shown in FIG. 6.

In this step, the first thermal conductive dielectric layer 161 is, for example, deposited on the surface of the semiconductor structure by using low-temperature PVD (Physical Vapor Deposition) technique, and may cover a surface of the P-type current spreading layer 150, a sidewall of the isolation trench, a portion (which is exposed to the mesa surface) of the N-type semiconductor layer 113, the N-type ohmic contact 120, and the adhesive layer 104.

The first thermal conductive dielectric layer 161 is one or a combination of some of BN, AlN, BeO, and diamond films, and has a total thickness ranging from 100 nm to 5 μm. The low-temperature PVD preparation method is one or a combination of some of sputtering, reactive plasma deposition (RPD) and atomic layer deposition (ALD).

In this embodiment, the first thermal conductive dielectric layer 161 is formed by sputtering process. The first thermal conductive dielectric layer 161 may be made of AlN, and may have a thickness of 400 nm.

Then, a contact hole 105 exposing the N-type ohmic contact 120 is formed in the first thermal conductive dielectric layer 161, for example, by performing photolithography and dry etching process, as shown in FIG. 7.

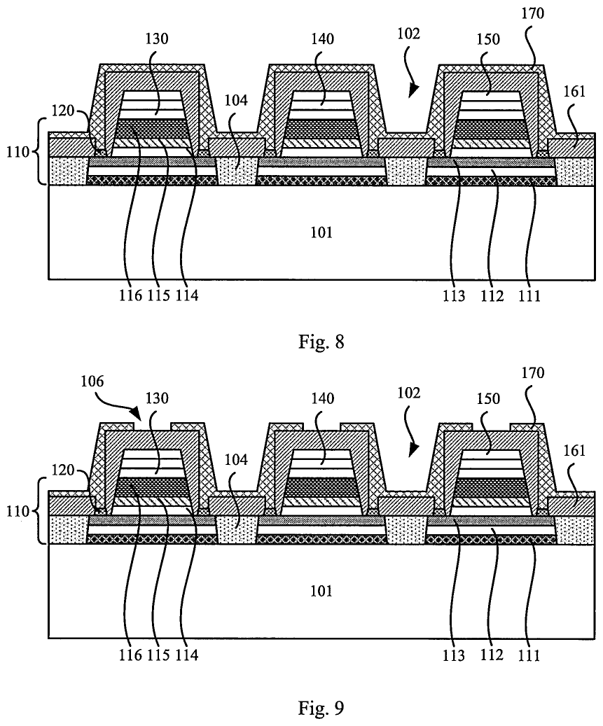

Further, an N-type current spreading layer 170 covering the first thermal conductive dielectric layer 161 is formed, as shown in FIG. 8.

In this step, the N-type current spreading layer 170 is, for example, formed by performing physical vapor deposition process, wherein the N-type current spreading layer 170 is connected to the N-type ohmic contact 120 via the contact hole 105.

In this embodiment, material of the N-type current spreading layer 170 may include Ti, Au, Pt and Ti.

Then, an opening 106 corresponding to each epitaxial unit and exposing a portion of the first thermal conductive dielectric layer 161 is, for example, formed by performing photolithography and dry etching process, as shown in FIG. 9.

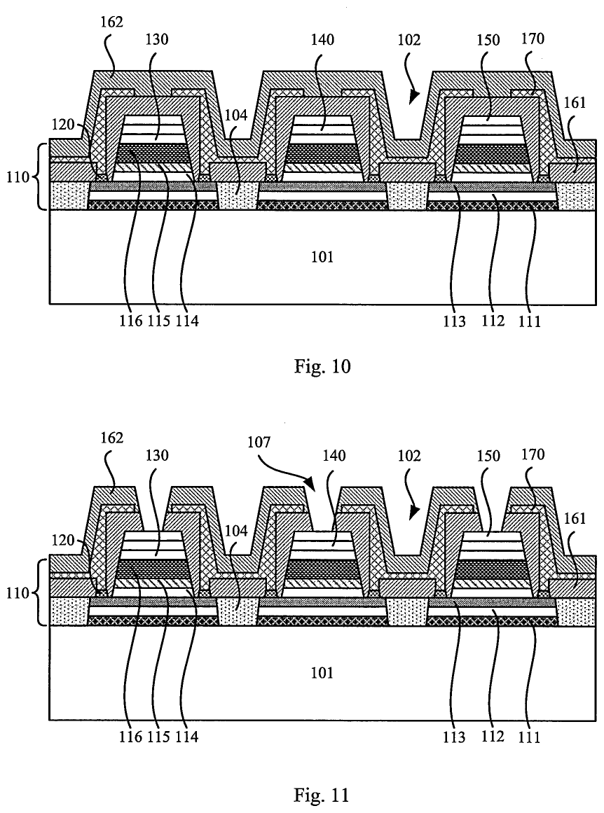

Further, a second thermal conductive dielectric layer 162 covering the N-type current spreading layer 170 is formed, as shown in FIG. 10.

In this step, the second thermal conductive dielectric layer 162 is deposited on the surface of the semiconductor structure, for example, by using low-temperature PVD technique, and may cover the N-type current spreading layer 170, and a portion of the second thermal conductive dielectric layer 162 is filled in the opening and connected to the first thermal conductive dielectric layer 161.

The second thermal conductive dielectric layer 162 is one or a combination of some of BN, AlN, BeO, and diamond films, and has a total thickness ranging from 100 nm to 5 μm. The low-temperature PVD preparation method is one or a combination of some of sputtering, reactive plasma deposition (RPD) and atomic layer deposition (ALD).

In this embodiment, the second thermal conductive dielectric layer 162 may be formed by performing sputtering and made of BN with a thickness of 400 nm.

Further, a P-type conductive via 107 is formed, as shown in FIG. 11.

In this step, the P-type conductive via 107 is formed, for example, by performing photolithography and dry etching process, wherein the P-type conductive via 107 passes through the second thermal conductive dielectric layer 162 and the first thermal conductive dielectric layer 161 in sequence at each opening 106 to expose a portion of the P-type current spreading layer 150. The size of the P-type conductive via 107 can be controlled to prevent the N-type current spreading layer 170 from being exposed to sidewalls of the P-type conductive via 107. The first thermal conductive dielectric layer 161 and the second thermal conductive dielectric layer 162 constitute a thermal conductive dielectric layer.

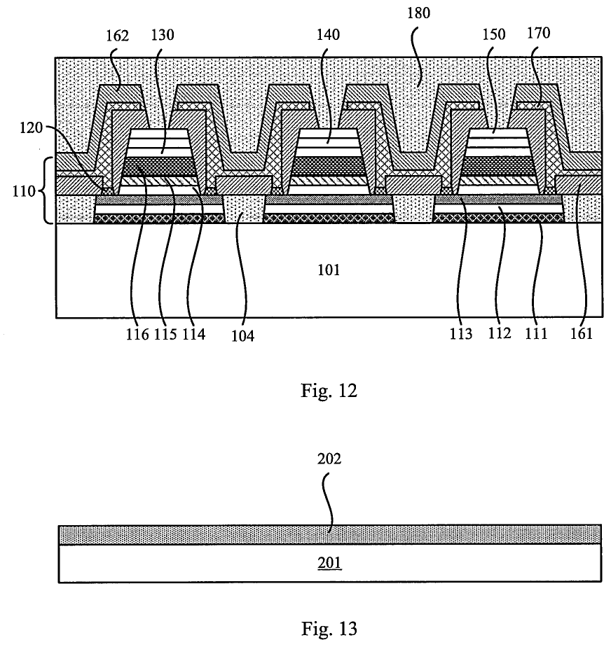

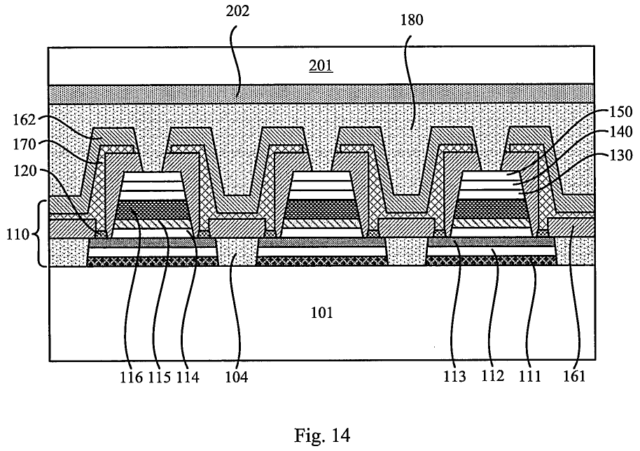

Further, a first bonding layer 180 covering the second thermal conductive dielectric layer 162 is formed, as shown in FIG. 12, wherein the first bonding layer 180 is connected to the P-type current spreading layer 150 through the P-type conductive via 107. Further, a second bonding layer 202 is formed on the second substrate 201, as shown in FIG. 13, and then the first bonding layer 180 is bonded with the second bonding layer 202, as shown in FIG. 14.

The first bonding layer 180 and the second bonding layer 202 are one of binary eutectic metal systems consisting of high melting point metal (such as Au, Ni, Cu and Ag) and low melting point metal (such as Sn and In), and a bonding principle thereof is one of eutectic bonding and transient liquid phase bonding. The second substrate 201 is one of Cu, Mo, W, CuW, CuMo, and AlSi substrates.

In this embodiment, the second substrate 201 is a CuMo metal substrate, the first bonding layer 180 and the second bonding layer 202 are both metal bonding layers made of Au, In, and the first bonding layer 180 and the second bonding layer 202 are bonded by using AuIn eutectic bonding, under bonding temperature of 240° C.

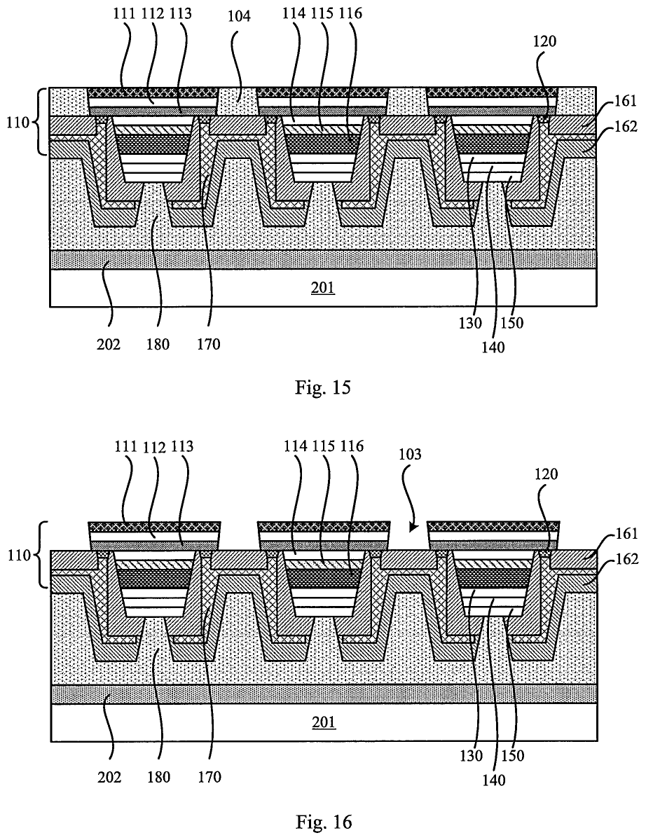

Further, the sapphire substrate 101 is removed, as shown in FIG. 15.

In this step, for example, light spot with energy density of 0.9 J/cm² generated by ArF excimer laser with a wavelength of 193 nm can be used to perform lift-off and decomposition of the AlN layer 111 spot by spot, so as to form Al metal and nitrogen gas. The Al metal formed by the decomposition of the AlN layer 111 is then removed by a chemical wet etching process, by using etching agent which is weak acidic or weak alkaline, such as weak acidic solution of dilute hydrochloric acid, oxalic acid, hydrofluoric acid, BOE, or weak alkaline solution of KOH, NaOH, TMAH.

In this embodiment, the second mesa unit in each epitaxial unit has a square planar shape and has a bottom surface with a side length L2 of 310 μm, and a minimum spacing between adjacent second mesa units is 40 μm, thus a side length of one epitaxial unit is 350 μm. The AlN layer 111 in a single epitaxial unit is lifted off and decomposed by light spot with a critical dimension larger than a critical dimension of the epitaxial unit, wherein the light spot can ensure that the AlN layer 111 in each epitaxial unit is fully irradiated (the light spot must be larger than the shape of the second mesa unit, for example, the light spot which is square and has a side length of 330 μm is larger than the second mesa unit whose planar shape is a square and has a side length of 310 μm), and a margin of 20 μm is reserved. A moving step distance of the light spot in the horizontal direction (X direction and Y direction) may be 350 μm, so that each epitaxial unit can be lifted off and decomposed spot by spot. In this process, the adhesive layer 104 can relieve stress and reduce the risk of cracking the epitaxial structure 110 when the substrate is being lifted off. Then, the semiconductor structure is immersed in oxalic acid solution, and the Al metal generated by the decomposition of the AlN layer 111 is removed, thus the sapphire substrate and the epitaxial structure 110 can be separated. Because laser lift-off is performed by irradiating from the sapphire surface, a portion, which is closest to the sapphire substrate 101 in position, of the AlN layer 111 absorbs laser energy and is decomposed, and a thickness of the decomposed portion is generally only about tens of nanometers, so there is a remained portion of the AlN layer 111. Lifting off the sapphire substrate by this method can avoid damage to the epitaxial structure 110 as much as possible. Of course, those skilled in the art can make other choices of laser as needed, and can set the area of laser light spot more flexibly according to a size corresponding to the epitaxial units (for example, setting the area of laser light spot to be slightly larger than a size of a single epitaxial unit or an overall size of two or more of the plurality of epitaxial units).

In some other embodiments, wet etching process or ICP (inductively coupled plasma) dry etching process with chemical etching properties can also be used to roughen the surface of epitaxial structure 110, so as to increase vertical light emission.

Further, the adhesive layer 104 is removed to expose the second trench 103 again, as shown in FIG. 16.

In this step, the adhesive layer 104 is removed, for example, by plasma process, in which the process gas is, for example, one of O-based gas, F-based gas, and a mixture of O-based gas and F-based gas. In this embodiment, the adhesive layer 104 can be removed using O₂ plasma.

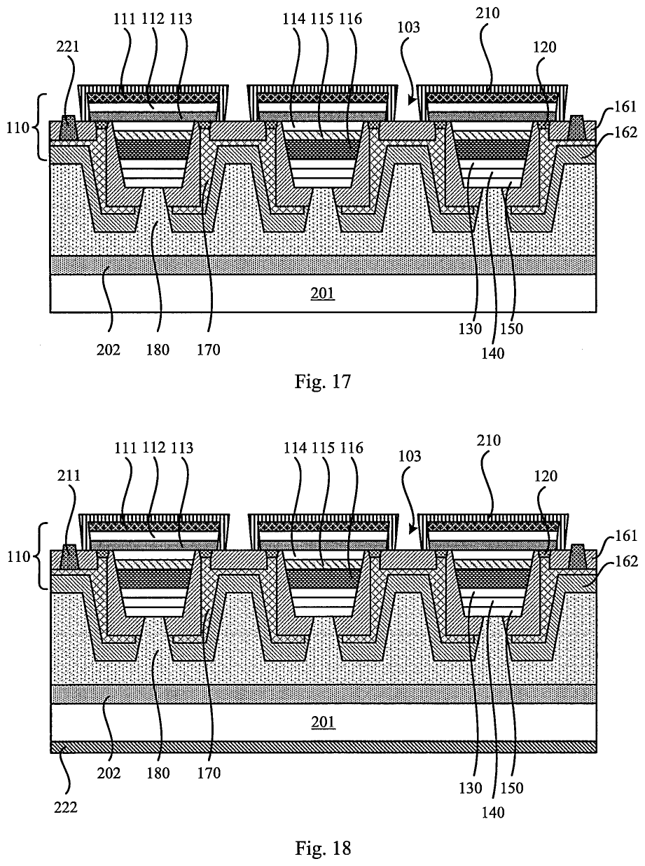

Further, an N-electrode 211 is formed at an edge of the epitaxial structure 110, as shown in FIG. 17.

In this step, the N-electrode 211 is formed, for example, by performing photolithography and physical vapor deposition process, wherein the N-electrode 211 is connected to the N-type current spreading layer 170 through the first thermal conductive dielectric layer 161. In this embodiment, the N-electrode 211 may be made of Ti, Pt, Au. The N-electrode 211 corresponds a position at an edge of the epitaxial structure 110 or at the periphery of the epitaxial unit array.

In this embodiment, the N-electrode 211, the N-type current spreading layer 170, and the plurality of N-type ohmic contacts 120 together constitute an N-type conductive path, which is located on a side opposite to the second surface of the epitaxial structure and is connected with the N-type semiconductor layer 113 of each epitaxial unit, thereby reducing shielding effect on the light-emitting surface caused by the N-electrode 211.

Further, a passivation layer 210 covering a surface of the epitaxial structure 110 and a sidewall of the second trench 103 is formed, as shown in FIG. 17, wherein the passivation layer 210 is connected to the first thermal conductive dielectric layer 161, material of the passivation layer 210 includes but is not limited to SiO₂, wherein deep ultraviolet light is emitted from a surface of the passivation layer 210.

Further, a P-electrode 222 is formed on a back surface of the second substrate 201, as shown in FIG. 18, wherein the P-electrode 222 may cover an entire back surface of the second substrate 201 and may be made of Ti, Au. In this embodiment, the P-type ohmic contact layer 130, the reflector layer 140, the P-type current spreading layer 150, the first bonding layer 180, the second bonding layer 202, the second substrate 201, and the P-electrode 222 together constitute a P-type conductive path, which is located on the first surface of the epitaxial structure and is connected with the P-type semiconductor layer of each epitaxial unit.

Then, the metal substrate is diced to split and separate adjacent die units, thus single deep ultraviolet LED die can be formed. Method of the dicing may be achieved using one of water-jet guided laser and laser dicing process, with a dicing scheme which is one of single-sided dicing or double-sided dicing.

According to the manufacturing method of the first embodiment of the present disclosure, the formed deep ultraviolet LED has an array-type vertical structure. The specific structure of the deep ultraviolet LED according to the first embodiment is described with reference to FIGS. 1 to 18, and will not be described here again.

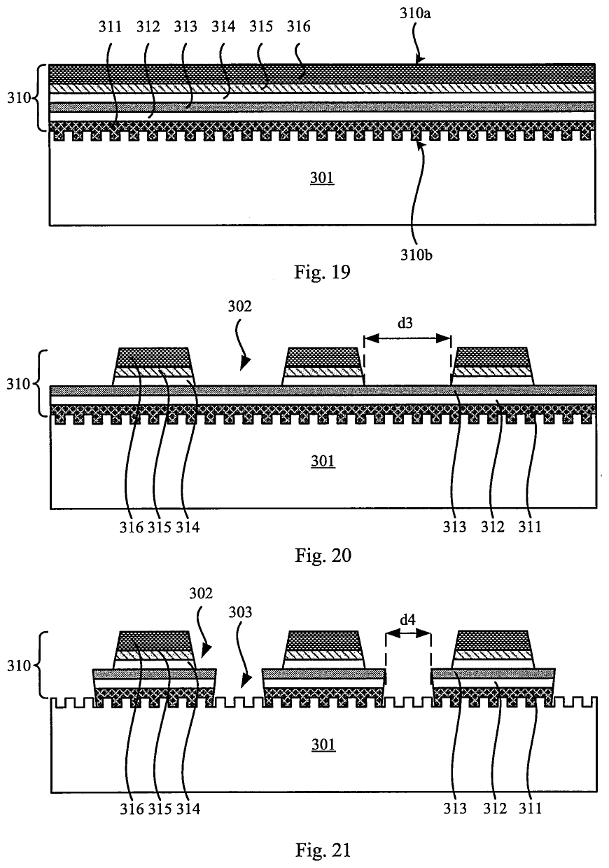

FIGS. 19 to 25 show structural diagrams of some stages of a manufacturing method of a deep ultraviolet LED according to a second embodiment of the present disclosure.

As shown in FIG. 19, an epitaxial structure 310 is formed on a sapphire substrate 301. The epitaxial structure 310 has a first surface 310a and a second surface 310b, which is opposite to the first surface 310a and is connected to the sapphire substrate 301. Along a direction from the second surface 310b to the first surface 310a of the epitaxial structure 310, the epitaxial structure 310 includes an AlN layer 311, a superlattice structure layer 312, an N-type semiconductor layer 313, a multi-quantum well layer 314, a P-type AlGaN layer 315, and a P-type GaN layer 316 stacked on the sapphire substrate 301 in sequence.

The epitaxial structure 310 of the present embodiment is substantially identical to that of the first embodiment and the similarities will not be described here again, except that the sapphire substrate 301 of the present disclosure is a patterned sapphire substrate with a pre-deposited AlN layer which has a thickness of 20 nm and is deposited by sputtering technique.

Further, a portion of the epitaxial structure 310 is removed, so as to form a first trench 302, as shown in FIG. 20. A stacked structure composed of the multi-quantum well layer 314, the P-type AlGaN layer 315, and the P-type GaN layer 316 is divided into a plurality of first mesa units by one or more first trenches 302. A minimum spacing d3 between adjacent first mesa units is, for example, 100 μm. The structures and formation processes of the first trench 302 and the first mesa unit can refer to the first embodiment and will not be described here again.

Different from the first embodiment, in this embodiment, each of the first mesa units is a frustum of rectangular pyramid, whose planar shape is a rectangle, and has a bottom rectangle surface (a surface, which is adjacent to the N-type semiconductor layer 313, of the multi-quantum well layer 314) with a length of 300 μm and a width of 250 μm, and the length and the width of the bottom surface are critical dimensions of a shape of the first mesa unit.

Further, a portion of the epitaxial structure 310 is removed, thus a second trench 303 can be formed, as shown in FIG. 21. A stacked structure composed of the N-type semiconductor layer 313, the superlattice structure layer 312, and the AlN layer 311 is divided into a plurality of second mesa units by one or more second trenches 303, the plurality of second mesa units have one-to-one correspondence to the plurality of first mesa units, respectively, in position and shape. The first trench 302 is connected with the second trench 303 to form a complete isolation trench. A minimum spacing d4 between adjacent second mesa units may be 40 μm. Structures and formation processes of the second trench 303 and the second mesa unit can refer to the first embodiment and will not be described here again.

Different from the first embodiment, in the present embodiment, each of the second mesa units is a frustum of rectangular pyramid, whose planar shape is a rectangle, and has a top rectangle surface (i.e., a surface, which is adjacent to the multi-quantum well layer 314, of the N-type semiconductor layer 313) with a length of 360 μm and a width of 310 μm. A cross-sectional shape, which is obtained along a thickness direction of the epitaxial layer structure 310, of each of the second mesa units may be an inverted trapezoid, that is, each of the second mesa units has a top surface area larger than its bottom surface area.

In some other embodiments, for example, sidewalls of the first mesa unit and the second mesa unit are roughened by using one of low-concentration alkaline solutions KOH, NaOH and TMAH, thus a triple-prism-shaped roughened structure can be formed, which improves light extraction efficiency of horizontal light output of the deep ultraviolet LED. Concentration of the alkaline solution is less than 20%, temperature of the alkaline solution is room temperature or ranges from 40° C. to 150° C., and roughening time ranges from 5 min to 60 min.

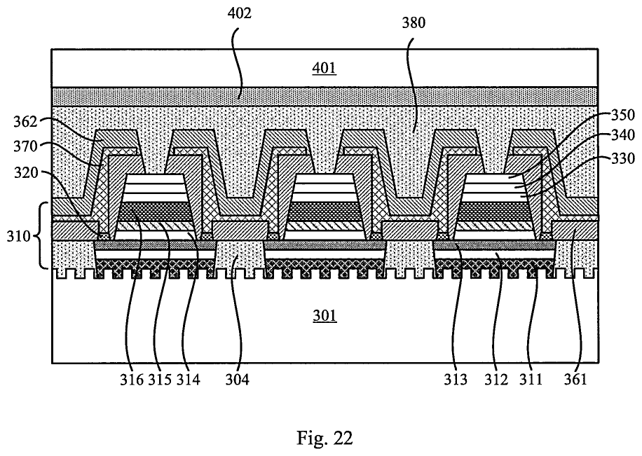

Further, a semiconductor structure, comprising an N-type ohmic contact 320, a P-type ohmic contact layer 330, a reflector layer 340, a P-type current spreading layer 350, an adhesive layer 304, a first thermal conductive dielectric layer 361, an N-type current spreading layer 370, a second thermal conductive dielectric layer 362, and a first bonding layer 380, is formed, and is bonded to a second substrate 401 on which a second bonding layer 402 is arranged, as shown in FIG. 22. The above structures and the formation processes thereof can be described with reference to the first embodiment and will not be described here again.

Differences from the first embodiment is that, in this embodiment, the N-type ohmic contact 320 includes Cr, Al, Ti, Au metal layers stacked in sequence: the P-type ohmic contact layer 330 includes a 50 nm thick Ni metal layer and a 50 nm thick Au metal layer stacked in sequence: the reflector layer 340 is an Al reflector made of Al, Ti, Pt, and Ti materials stacked in sequence: the P-type current spreading layer 350 is made of Ti, Pt, Au, Pt and Ti materials stacked in sequence; the first thermal conductive dielectric layer 361 and the second thermal conductive dielectric layer 362 are made of AlN, and each have a thickness of 800 nm; the N-type current spreading layer 370 is made of Ti, Pt, Au, Pt, Ti materials stacked in sequence: the second substrate 401 is a CuW metal substrate, the first bonding layer 380 and the second bonding layer 402 are both metal bonding layers made of Cu, In, and the first bonding layer 380 and the second bonding layer 402 are eutectically bonded by use of CuIn.

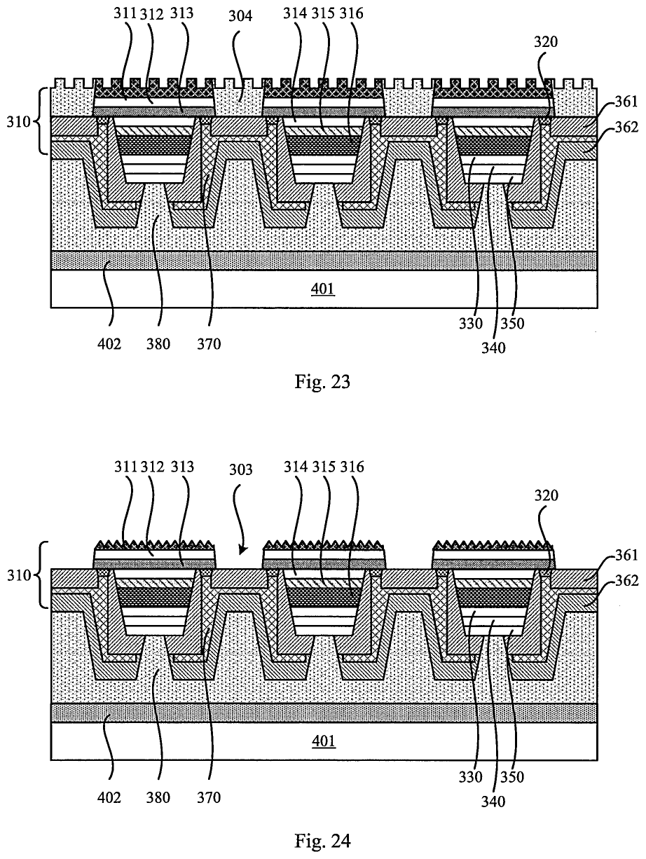

Further, the sapphire substrate 301 is removed, as shown in FIG. 23.

In this step, for example, light spot with energy density of 1.2 J/cm² generated by ArF excimer laser with a wavelength of 193 nm can be used to perform lift-off and decomposition of the AlN layer 311 spot by spot, so as to generate Al metal and nitrogen gas. The Al metal formed by the decomposition of the AlN layer 311 is then removed by a chemical wet etching process, by using etching agent which is weak acidic or weak alkaline, such as weak acidic dilute solution of hydrochloric acid, oxalic acid, hydrofluoric acid, BOE, or weak alkaline solution of KOH, NaOH, TMAH.

In this embodiment, the second mesa unit in each epitaxial unit has a rectangular planar shape and has a top surface with a length of 360 μm and a width of 310 μm, and a minimum spacing between adjacent second mesa units is 40 μm, thus a width and a length of one epitaxial unit may be 350 μm and 400 μm, respectively. Lift-off and decomposition are performed on the AlN layer 311 in a single epitaxial unit by using rectangular light spot with a length of 330 μm and a width of 380 μm. Moving step distances of the light spot in the horizontal directions (i.e., X direction and Y direction) may be 350 μm and 400 μm, respectively. Then, the semiconductor structure is immersed in TMAH solution, and the Al metal generated by the decomposition of the AlN layer 311 is removed, thus the sapphire substrate and the epitaxial structure 310 can be separated.

In some other embodiments, the AlN material may also be chemically etched using KOH solution at 70° C. to form a hexagonal pyramid roughened surface with a critical dimension ranging of hundreds of nanometers on the epitaxial structure 310, so as to increase vertical light emission, as shown in FIG. 24.

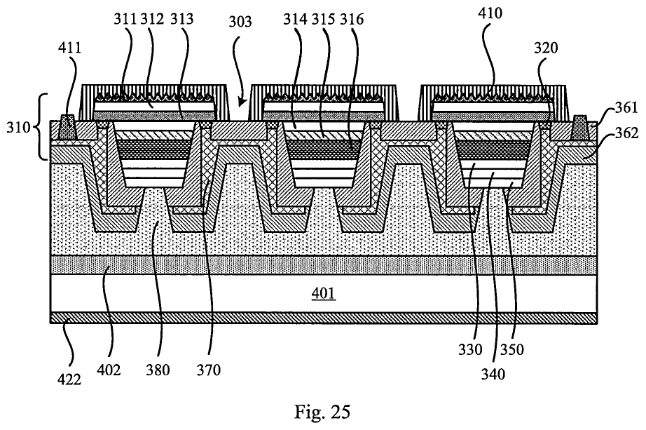

Further, an N-electrode 411, a P-electrode 422, and a passivation layer 410 are formed, as shown in FIG. 25. Formation processes and structures of the N-electrode 411, the P-electrode 422, and the passivation layer 410 can be described with reference to the first embodiment, and will not be described here again.

Different from the first embodiment, in this embodiment, the N-electrode 411 may be made of Cr, Pt, Au, and the P-electrode 422 may be made of Ti, Pt, Au.

Then, the metal substrate is diced to split and separate adjacent die units, thus single deep ultraviolet LED die can be formed. Method of the dicing may be achieved using one of water-jet guided laser and laser dicing process, with a dicing scheme which is one of single-sided dicing and double-sided dicing.

According to the manufacturing method of the second embodiment of the present disclosure, the formed deep ultraviolet LED has an array-type vertical structure. The specific structure of the deep ultraviolet LED according to the second embodiment is described with reference to FIGS. 19 to 25, and will not be described here again.

According to deep ultraviolet LEDs and manufacturing methods thereof provided by embodiments of the present disclosure, by dividing an epitaxial structure into a plurality of epitaxial units arranged in an array, when an AlN layer in each epitaxial unit is irradiated by laser through a sapphire substrate, an area of laser light spot can be set more flexibly according to a size corresponding to the epitaxial units (for example, the area of the laser light spot is set to be slightly larger than a size of a single epitaxial unit or an overall size of two or more of the plurality of epitaxial units), instead of setting the light spot to have a large area matched with an overall size of the deep ultraviolet LED, thus mitigating a problem of serious damage to the epitaxial structure caused by strong impact generated at a moment of high energy density laser lift-off.

An adhesive layer is formed on a portion, which is exposed between adjacent epitaxial units, of the sapphire substrate. When the irradiated AlN layers in the epitaxial units are decomposed into Al metal and nitrogen gas one by one by laser lift-off process, high pressure nitrogen gas release and plasma impact on adjacent epitaxial units produced at a moment of laser lift-off can be reduced, that is, a probability of the epitaxial structure cracking in the lift-off process of AlN material can be reduced by using this adhesive layer as a stress release structure.

Furthermore, the adhesive layer can be made of cured UV adhesive or polydimethylsiloxane, which has stronger support strength compared with resin material, and can solve a problem of serious failure caused by aging of resin material under deep ultraviolet irradiation, thereby improving lift-off yield and reliability of the deep ultraviolet LED.

The sapphire substrate is separated from the epitaxial structure by dissolving the Al metal produced by decomposing the AlN layer by chemical wet etching process, and then the sapphire substrate is lifted off from the epitaxial structure. The chemical wet etching process adopts weak acidic or weak alkaline solution, which can reduce the probability of damage caused by etching solution to materials other than Al metal.

In the deep ultraviolet LED, each epitaxial unit is divided into two parts: a first mesa unit and a second mesa unit, the second mesa unit has a mesa surface protruding from the first mesa unit, and the N-type semiconductor layer is exposed to the mesa surface, so that the N-type ohmic contact can be directly deposited on the mesa surface (on a surface of Ga/Al polarity N-AlGaN). Compared with the surface contact of metal and N polarity N-AlGaN in the prior art, the ohmic contact performance of the metal-N-type semiconductor are improved, thereby alleviating the voltage problem of the deep ultraviolet LED and realizing a more reasonable voltage level of the deep ultraviolet LED.

Because the N-type ohmic contact and the N-type current spreading layer are located on a same side of the N-type semiconductor layer and opposite to the light-emitting surface, the N-electrode located at the edge of the epitaxial structure is connected with each N-type ohmic contact through the N-type current spreading layer, which replaces the scheme of forming the N-electrode on the light-emitting surface of the N-type semiconductor layer, reduces influence to the light-emitting surface, and relaxes limitations to material of the N-electrode. By arranging a plurality of N-type ohmic contacts on the N-type semiconductor layer and increasing the number of the plurality of N-type ohmic contacts or a contact area of the N-type ohmic contacts with the N-type semiconductor layer, a problem of poor current spreading performance due to the natural characteristics of the n-AlGaN layer can be alleviated. Further, combined with a layout distribution of the N-type current spreading layer, point-shaped N-electrode (or small-size N-electrode) can provide power supply to the N-type semiconductor layer in each epitaxial unit.

In addition, by controlling the morphology of the first trench and the second trench, making the cross sections of the first mesa unit and the second mesa unit each be a trapezoid or an inverted trapezoid in shape, area of a sidewall of each epitaxial unit is increased, thus facilitating the extraction of more horizontal deep ultraviolet light, and further improving the light-emitting effect of the deep ultraviolet LED.

Therefore, the vertical structure deep ultraviolet LED provided by embodiments of the present disclosure can operate under large current and high thermal conduction, and has great significance for realizing industrialization of high-standard deep ultraviolet LED.

Embodiments of the present disclosure have been described above. However, these embodiments are for illustrative purposes only and are not intended to limit the scope of the present invention. The scope of the invention is defined by the appended claims and their equivalents. Without departing from the scope of the present invention, many kinds of alternative and modification may be made by those skilled in the art and should fall within the scope of the present invention.

1. A manufacturing method of a vertical structure deep ultraviolet LED, wherein the manufacturing method comprises:
forming an epitaxial structure on a sapphire substrate, the epitaxial structure having a first surface and a second surface, the second surface being connected with the sapphire substrate;
dividing the epitaxial structure into a plurality of epitaxial units arranged in an array, a portion of the sapphire substrate being exposed between adjacent ones of the plurality of epitaxial units;
forming an adhesive layer on a portion, which is exposed between adjacent ones of the plurality of epitaxial units, of the sapphire substrate;
bonding a second substrate above the first surface of the epitaxial structure;
performing laser lift-off to the sapphire substrate; and
removing the adhesive layer.

2. The manufacturing method according to claim 1, wherein the epitaxial structure comprises an AlN layer exposed to the second surface, and step of performing laser lift-off to the sapphire substrate comprises:
irradiating the AlN layer in each of the plurality of epitaxial units with laser through the sapphire substrate to decompose an irradiated portion of the AlN layer into Al metal and nitrogen gas; and
removing the Al metal by chemical wet etching process to separate the sapphire substrate from the epitaxial structure,
wherein step of irradiating the AlN layer in each of the plurality of epitaxial units with laser through the sapphire substrate to decompose the irradiated portion of the AlN layer into Al metal and nitrogen gas comprises:
decomposing the irradiated portions of the AlN layer in the plurality of epitaxial units into Al metal and nitrogen gas one by one using an ArF excimer laser lift-off process.

3. (canceled)

4. (canceled)

5. The manufacturing method according to claim 1, wherein the adhesive layer is made of cured ultraviolet adhesive or polydimethylsiloxane, and/or step of removing the adhesive layer comprises:
removing the adhesive layer using plasma etching process.

6. The manufacturing method according to claim 1, wherein the array is a rectangular array or a hexagonal array,
and a spacing between adjacent ones of the plurality of epitaxial units is greater than 50 μm.

7. The manufacturing method according to claim 2, wherein the epitaxial structure further comprises: a P-type semiconductor layer, an N-type semiconductor layer, a multi-quantum well layer sandwiched between the P-type semiconductor layer and the N-type semiconductor layer, and a superlattice layer between the N-type semiconductor layer and the AlN layer, wherein the P-type semiconductor layer is exposed to the first surface of the epitaxial structure,
and step of dividing the epitaxial structure into the plurality of epitaxial units arranged in the array comprises:
forming a first trench penetrating the P-type semiconductor layer and the multi-quantum well layer, a portion of a surface of the N-type semiconductor layer being exposed to the first trench; and
forming a second trench penetrating the N-type semiconductor layer, the superlattice layer and the AlN layer through the first trench, a portion of the sapphire substrate being exposed to the second trench, the first trench being connected with the second trench to divide the epitaxial structure into the plurality of epitaxial units arranged in the array,
wherein the adhesive layer is filled in the second trench,
wherein a width of the second trench is less than a width of the first trench, each of the plurality of epitaxial units comprises a first mesa unit and a second mesa unit, adjacent first mesa units are separated by the first trench, adjacent second mesa units are separated by the second trench,
wherein in each of the plurality of epitaxial units, the second mesa unit has a mesa surface protruding from the first mesa unit, a portion of the N-type semiconductor layer is exposed to the mesa surface,
wherein the manufacturing method further comprises: forming an N-type ohmic contact on each of the mesa surfaces, wherein the N-type ohmic contact is connected with the N-type semiconductor layer.

8. (canceled)

9. The manufacturing method according to claim 7, wherein along a direction from the first surface to the second surface of the epitaxial structure, a cross-sectional shape of the first mesa unit is a trapezoid or an inverted trapezoid, and a cross-sectional shape of the second mesa unit is a trapezoid or an inverted trapezoid.

10. The manufacturing method according to claim 87, further comprising:
forming a P-type ohmic contact layer on the P-type semiconductor layer of each of the plurality of epitaxial units;
forming a reflector layer on the P-type ohmic contact layer of each of the plurality of epitaxial units;
forming a P-type current spreading layer on the reflector layer of each of the plurality of epitaxial units,
wherein an opening of the first trench extends to the P-type current spreading layer, and the manufacturing method further comprises: forming a first thermal conductive dielectric layer covering the P-type current spreading layer, a sidewall of the first trench, a portion, which is exposed to the mesa surface, of the N-type semiconductor layer, and the adhesive layer,
wherein the first thermal conductive dielectric layer has a contact hole exposing the N-type ohmic contact,
wherein the manufacturing method further comprises: forming an N-type current spreading layer covering the first thermal conductive dielectric layer, wherein, the N-type current spreading layer is connected to each of the N-type ohmic contacts via the contact hole, and the N-type current spreading layer has an opening which corresponds to each of the plurality of epitaxial units and exposes the first thermal conductive dielectric layer,
wherein the manufacturing method further comprises: forming a second thermal conductive dielectric layer covering the N-type current spreading layer, wherein a portion of the second thermal conductive dielectric layer is filled in the opening of the N-type current spreading layer and is connected to the first thermal conductive dielectric layer; and forming a P-type conductive via which passes through the second thermal conductive dielectric layer and the first thermal conductive dielectric layer in sequence at each of the openings of the N-type current spreading layer to expose a portion of the P-type current spreading layer.

11. (canceled)

12. (canceled)

13. (canceled)

14. The manufacturing method according to claim 10, wherein step of bonding the second substrate above the first surface of the epitaxial structure comprises:
forming a first bonding layer covering the second thermal conductive dielectric layer, the first bonding layer being connected to the P-type current spreading layer through the P-type conductive via;
forming a second bonding layer on the second substrate;
bonding the first bonding layer with the second bonding layer.

15. (canceled)

16. The manufacturing method according to claim 14, further comprising: forming a passivation layer covering the second surface of the epitaxial structure and sidewalls of each of the second mesa units,
wherein, the passivation layer is connected with the first thermal conductive dielectric layer,
wherein the manufacturing method further comprises:
forming a P-electrode, wherein the P-electrode and the second bonding layer are respectively located on opposite sides of the second substrate; and
forming an N-electrode at an edge of the epitaxial structure, the N-electrode being connected to the N-type current spreading layer through the first thermal conductive dielectric layer along a direction from the second surface to the first surface,
wherein the second substrate is a metal substrate, and the manufacturing method further comprises: dicing the metal substrate to separate adjacent deep ultraviolet LEDs, by using one of dicing processes including water-jet guided laser dicing process and laser dicing process, and one of dicing schemes including single-side dicing scheme and double-side dicing scheme.

17. (canceled)

18. (canceled)

19. An epitaxial structure of a vertical structure deep ultraviolet LED, wherein the epitaxial structure has a first surface and a second surface opposite to the first surface, and is divided into a plurality of epitaxial units arranged in an array, each of the plurality of epitaxial units comprises an AlN layer, a P-type semiconductor layer, an N-type semiconductor layer, and a multi-quantum well layer sandwiched between the P-type semiconductor layer and the N-type semiconductor layer, the P-type semiconductor layer is exposed to the first surface of the epitaxial structure and the AlN layer is exposed to the second surface of the epitaxial structure,
wherein each of the plurality epitaxial units comprises a first mesa unit and a second mesa unit, and the first mesa unit comprises the P-type semiconductor layer and the multi-quantum well layer, the second mesa unit comprises the AlN layer and the N-type semiconductor layer, and the second mesa unit has a mesa surface protruding from the first mesa unit.

20. (canceled)

21. The epitaxial structure according to claim 19, wherein the array is a rectangular array or a hexagonal array,
a spacing between adjacent ones of the plurality of epitaxial units is greater than 50 μm,
wherein along a direction from the first surface to the second surface of the epitaxial structure, a cross-sectional shape of the first mesa unit is a trapezoid or an inverted trapezoid, and a cross-sectional shape of the second mesa unit is a trapezoid or an inverted trapezoid.

22. (canceled)

23. A vertical structure deep ultraviolet LED, wherein the vertical structure deep ultraviolet LED comprises: an N-type ohmic contact, an N-type current spreading layer, an N-electrode, a P-type ohmic contact layer, a reflector layer, a bonding layer, a substrate, a P-electrode, and a thermal conductive dielectric layer; and
an epitaxial structure, which has a first surface and a second surface opposite to the first surface, and is divided into a plurality of epitaxial units arranged in an array, wherein each of the plurality of epitaxial units comprises a P-type semiconductor layer, an N-type semiconductor layer, and a multi-quantum well layer sandwiched between the P-type semiconductor layer and the N-type semiconductor layer, and the P-type semiconductor layer is exposed to the first surface of the epitaxial structure.

24. The vertical structure deep ultraviolet LED according to claim 23, wherein each of the plurality of epitaxial units has a first mesa unit and a second mesa unit, wherein the first mesa unit comprises the P-type semiconductor layer and the multi-quantum well layer, the second mesa unit comprises the N-type semiconductor layer, and the second mesa unit has a mesa surface protruding from the first mesa unit.

25. The vertical structure deep ultraviolet LED according to claim 24, wherein the epitaxial structure further comprises an AlN layer exposed to the second surface of the epitaxial structure, and the second mesa unit further comprises the AlN layer.

26. The vertical structure deep ultraviolet LED according to claim 23, wherein the array is a rectangular array or a hexagonal array,
a spacing between adjacent ones of the plurality of epitaxial units is greater than 50 μm,
wherein along a direction from the first surface to the second surface of the epitaxial structure, a cross-sectional shape of the first mesa unit is a trapezoid or an inverted trapezoid, and a cross-sectional shape of the second mesa unit is a trapezoid or an inverted trapezoid.

27. (canceled)

28. The vertical structure deep ultraviolet LED according to claim 24, wherein a portion of the N-type semiconductor layer is exposed to the mesa surface, and the N- type ohmic contacts are located on each of the mesa surfaces, respectively, and are connected to the N-type semiconductor layer,
wherein the N-type current spreading layer is respectively connected with each of the N-type ohmic contacts, the N-type current spreading layer and each of the N-type ohmic contacts are located on a same side of the N-type semiconductor layer, and deep ultraviolet light is emitted from the second surface of the epitaxial structure,
wherein the vertical structure deep ultraviolet LED further comprises an array of reflector layers and an array of P-type current spreading layers, an array of the P-type ohmic contact layers are located on the first surface of the epitaxial structure and each of the P-type ohmic contact layers is connected with the P-type semiconductor layer in a corresponding one of the plurality of epitaxial units, and each of the reflector layers is located between a corresponding one of the P-type current spreading layers and a corresponding one of the P-type ohmic contact layers,
wherein the thermal conductive dielectric layer and each of the N-type ohmic contacts are located on a same side of the N-type semiconductor layer, the thermal conductive dielectric layer wraps the first mesa units and the array of the P-type ohmic contact layers, the array of the P-type current spreading layers and the array of the reflector layers, and extends to the mesa surface, adjacent ones of the mesa surfaces are connected via the thermal conductive dielectric layer, and the thermal conductive dielectric layer is exposed between the adjacent second mesa units along a direction from the second surface to the first surface,
wherein each of the N-type ohmic contacts and the N-type current spreading layer are located in the thermal conductive dielectric layer,
wherein along a direction from the second surface to the first surface, the thermal conductive dielectric layer is also exposed at an edge of the epitaxial structure, the N-electrode is located at the edge of the epitaxial structure and is connected to the N-type current spreading layer through a portion of the thermal conductive dielectric layer along a direction from the second surface to the first surface.

29. (canceled)

30. (canceled)

31. (canceled)

32. (canceled)

33. The vertical structure deep ultraviolet LED according to claim 28, wherein the bonding layer comprises a first bonding layer and a second bonding layer, along a direction from the second surface to the first surface, the first bonding layer, the second bonding layer, the substrate, and the P-electrode are connected in sequence,
wherein, the first bonding layer and the thermal conductive dielectric layer are located on a same side of the N-type semiconductor layer and the first bonding layer is connected with a surface of the thermal conductive dielectric layer,
and along a direction from the first surface to the second surface, the first bonding layer is connected to each of the P-type current spreading layers through the thermal conductive dielectric layer, and the first bonding layer and the N-type current spreading layer are separated by the thermal conductive dielectric layer.

34. The vertical structure deep ultraviolet LED according to claim 23, wherein the substrate is a metal substrate.

35. The vertical structure deep ultraviolet LED according to claim 24, further comprising a passivation layer, which covers the second surface of the epitaxial structure and sidewalls of each of the second mesa units, and is connected to the thermal conductive dielectric layer.

36. The vertical structure deep ultraviolet LED according to claim 25, wherein each of the plurality of epitaxial units further comprises a superlattice structure layer, and in each of the second mesa units, the superlattice structure layer is located between the AlN layer and the N-type semiconductor layer.
